(19) United States
(12) Patent Application Publication
(10) Pub. No.: US 2005/0037536 A1
(43) Pub. Date: Feb. 17, 2005

(54) Semiconductor packaging structure and method for forming the same

(76) Inventor: Szu Yu Lai, Taipei Hsien (TW)

Correspondence Address: SZU YU LAI, 235 Chung-Ho, Box 8-24, Taipei, TW

(21) Appl. No.: 10/638,892

(22) Filed: Aug. 12, 2003

(51) Int. Cl. H01L 21/44

(52) U.S. Cl. 438/106

(57) ABSTRACT

A semiconductor packaging structure comprises a die; at least one pad on the die; a least one elastomers on a corresponding one of the at least one pad, wherein the at least one elastomer is made of conductive or non-conductive material; a first conductor on the elastomer; a second conductor located on the first conductor. The second conductor is directly welded to a substrate. Thermal expansion between the substrate and the die is absorbed by the strain of the elastomer and the extension of the first conductor. Furthermore, a method for forming the semiconductor packaging structure is disclosed.

### FIELD OF THE INVENTION

The present invention relates to semiconductor packaging structures, and particularly to a semiconductor packaging structure and the method for forming the same.

### BACKGROUND OF THE INVENTION

With the improvement of the IC technology, more and more lead pins are integrated in an IC (Integrated Circuit). Moreover, the size of the ICs become smaller and smaller. Thereby, the IC packaging by surface mounting technology can not satisfy the requirement of market. Current packaging ways include TSOP, BAG (ball grid array), CSP (chip scale package) and WLCSP (Wafer level CSP), etc. The TSOP has a too large lead frame and lead lines are too long and thus the delay time is long so that the transmission rate is low. Furthermore, the area can not be effectively reduced. The BGA needs a larger substrate so as to induce a longer delay time, although the function thereof is enhanced as compared with the TSOP, but the requirements of high transmission and low cost can not be achieved. Although CSP has such a function, the processes of wire bonding and encapsulation are required. Although the WLCSP need not package process, the solder ball is welded on the die directly. The coefficient of thermal expansion. (CTE) of a die is about 3-4 per million. When the die is welded to a substrate, since the substrate is too large (about 16-18), the reliability is affected. It is possible that the substrate breaks. Thereby, it is often that filler is filled between the substrate and the IC so as to fix the two. However, it is difficult to fill the filler (the yield rate is low) and the cost is high. Moreover, the cost of WLCSP is high and WLCSP need be executed by using an encapsulant machine. Due to above mentioned problems about TSOP, BAG (ball grid array), CSP (chip scale package) and WLCSP (Wafer level CSP), etc., U.S. Pat. No. 5,672,550, U.S. Pat. No. 6,329,497, EP1137067, JP61260649, etc., disclose methods to resolve the problem encountered in the prior art.

### SUMMARY OF THE INVENTION

Accordingly, the primary object of the present invention is to provide a semiconductor packaging structure which comprises a die; at least one pad on the die; a least one elastomers on a corresponding one of the at least one pad. The at least one elastomer is made of conductive or non-conductive material; a first conductor on the elastomer; a second conductor being located on the first conductor, The second conductor is directly welded to a substrate. Thermal expansion between the substrate and the die is absorbed by the strain of the elastomer and the extension of the first conductor.

Another object of the present invention is to provide a method for manufacturing a semiconductor packaging structure, comprising the steps of: coating, a first metal layer on a surface of a passivation layer of a wafer; coating a first photo-resistor layer on the first metal layer; exposing and developing the first photo-resistor layer for removing undesired portions to form a plurality of photo-resistors; etching the first metal layer to form a plurality of pads below the photo-resistors; removing the photo-resistors to expose the plurality of pads; coating a second photo-resistor layer coated upon the passivation layer and the plurality of pads; exposing and developing the second photo-resistors on the pads so that the portions of the second photo-resistor layer on the pads are removed to form openings which have a size small than the extent of the pads; filling elastomers into the openings; removing other second photo-resistor layer; coating a layer of second metal layer on the wafer; coating a third photo-resistor layer coated on the second metal layer; exposing and developing the second photo-resistor layer for forming openings, which is corresponding to the third photo-resistors of the elastomers; etching the second metal layer for forming a plurality of first conductors on the elastomers; forming a passivation layer around a periphery of each first conductor; forming a second conductor formed on the first conductor.

The various objects and advantages of the present invention will be more readily understood from the following detailed description when read in conjunction with the appended drawing.

### BRIEF DESCRIPTION OF THE DRAWINGS

FIG. 1 is a partial cross sectional view of the present invention showing the semiconductor packaging structure of the present invention.

FIG. 2 is a schematic view showing the process of the present invention.

### DETAIL DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

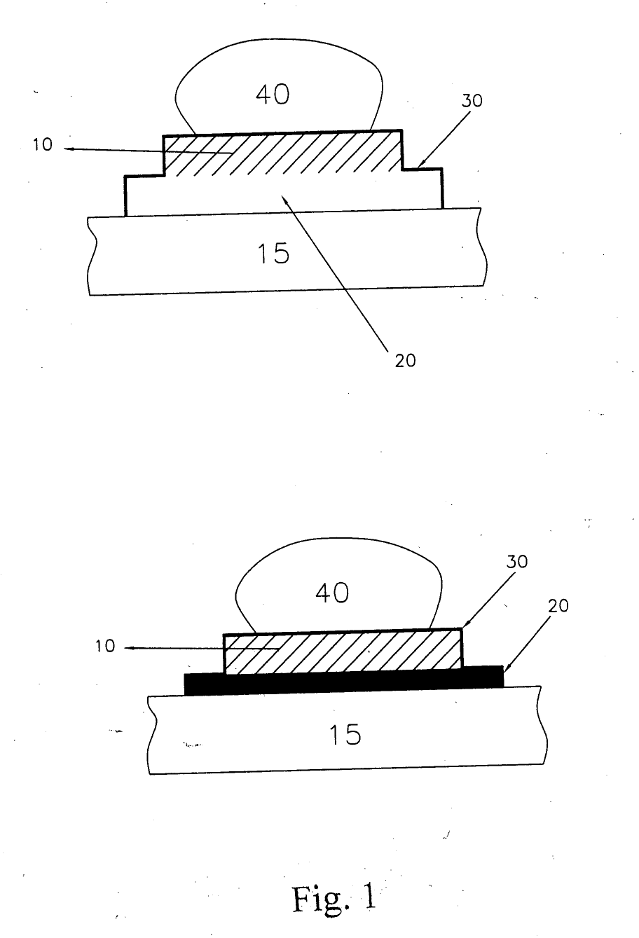

With reference to FIG. 1, it is illustrated that a die 10 is located as a base layer. Then a pad 20 is formed on the die 10. An elastomer 10 is formed on the pad 20. It is preferably that the elastomer 10 can be made be conductive material or non-conductive material, for example silicone. A first conductor 30 is formed on the elastomer 10. A second conductor 40 is located on the first conductor 30. The second conductor 40 is directly welded to a substrate (not shown). Thereby, the CTE (coefficient of thermal expansion) between the substrate and the die 15 can be absorbed by the strain of the elastomer 10 and the extension of the first conductor 30.

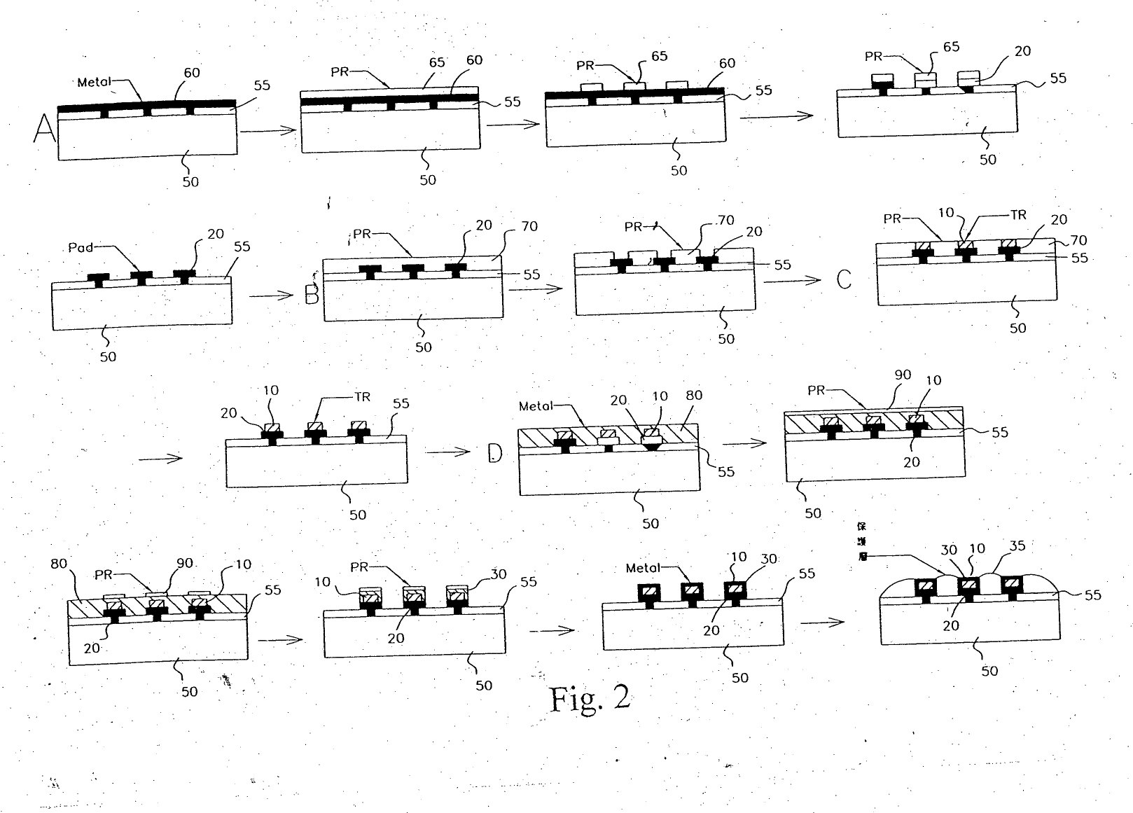

The manufacturing step of the present invention will be described herein with reference to FIG. 2.

A first metal layer 60 is coated on a surface of a passivation layer 55 of a wafer 50. Then a first photo-resistor layer 65 is coated on the first metal layer 60. Then the first photo-resistor layer 65 is exposed and developed so as to remove undesired portions to form a plurality of photo-resistors. Then the first metal layer 60 is etched to form a plurality of pads 20 below the photo-resistors 65. Then the photo-resistors 65 are removed so as to expose the plurality of pads 20.

Then a second photo-resistor layer 70 is coated upon the passivation layer 55 and the plurality of pads 20. Then the photo-resistor 70 on the pads 20 are exposed and developed so that the portions of the second photo-resistor layer 70 on the pads 20 are removed so as to formed openings which have a size small than the extent of the pads. Then elastomers 10 are filled into the openings. Then other second photo-resistor layer 70 is remvoed.

Then a layer of second metal layer 80 is coated upon the wafer (by for example sputtering, electric plating, chemical plating, etc.). A third photo-resistor layer 90 is coated on the second metal layer 80. After exposing and developing, openings are installed, which is corresponding to the third photo-resistors 90 of the elastomers 10. After etching, a plurality of first conductors 30 are formed upon the elastomers 10. Then, a periphery of each first conductor 30 is coated with a passivation layer 35. Finally, a second conductor 40 for contacting the substrate is formed on the first conductor 30.

Thereby, in the present invention, a pad 20 is formed on the die 10. An elastomer 10 is formed on the pad 20. It is preferably that the elastomer 10 can be made be conductive material or non-conductive material, for example silicone. A first conductor 30 is formed on the elastomer 10. A second conductor 40 is located on the first conductor 30. The second conductor 40 is directly welded to substrate (not shown). Thereby, the CTE (coefficient of thermal expansion) between the substrate and the die 15 can be absorbed by the strain of the elastomer 10 and the extension of the first conductor 30. Thus, the yield ratio is increased effectively. The die of the present invention has a high transmission rate, high density, and low cost. Moreover, the process of coating the elastomers on the pad can be performed by screen printing or steel printing, or the elastomers are encapsulated on the pad by an encapsulant machine, or the photo-resistors are directly used as elastomers. All these are within the scope of the present invention.

The advantages of the present invention will be described here.

Since the elastomers are formed between the pad and the conductors and the elastomers have preferred strain, when the IC is connected to a substrate, the strain due to the the CTE therebetween can be absorbed so as to prevent from deformation and striping so that the yield ratio is increased effectively.

Since to connect an IC to a substrate has a preferred effect, machines, such as wire bonding machines, encapsulant machines, etc. are not required. Thereby, some un-required processes can be reduced.

Thereby, from above said reasons, cost can be reduced due to the improvement of yield ratio, and reduction of manufacturing processes.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A semiconductor packaging structure comprising:
a die;
at least one pad oh the die;
a least one elastomer on a corresponding one of the at least one pad, wherein the at least one elastomer is made of conductive or non-conductive material;
a first conductor on the elastomer;
a second conductor being located on the first conductor; wherein the second conductor is directly welded to a substrate;
wherein thermal expansion between the substrate and the die is absorbed by strain of the elastomer and extension of the first conductor.

2. A method for manufacturing a semiconductor packaging structure, comprising the steps of:
coating a first metal layer on a surface of a passivation layer of a wafer;
coating a first photo-resistor layer on the first metal layer;
exposing and developing the first photo-resistor layer for removing undesired portions to form a plurality of photo-resistors;
etching the first metal layer to form a plurality of pads below the photo-resistors;
removing the photo-resistors to expose the plurality of pads;
coating a second photo-resistor layer coated upon the passivation layer and the plurality of pads;
exposing and developing the second photo-resistors on the pads so that the portions of the second photo-resistor layer on the pads are removed to form openings which have a size small than that of the pads;
filling elastomers into the openings;
removing other second photo-resistor layer;
coating a layer of second metal layer on the wafer;
coating a third photo-resistor layer on the second metal layer;
exposing and developing the second photo-resistor layer for forming openings, which is corresponding to the third photo-resistors of the elastomers;
etching the second metal layer for forming a plurality of first conductors on the elastomers;
forming a passivation layer around a periphery of each first conductor;
forming a second conductor formed on the first conductor.

3. The method as claimed in claim 2, wherein coating metal layer is performed by one way selected from sputtering, electric plating, chemical plating.

4. The method as claimed in claim 2, wherein the process of coating the elastomers on the pad is selected from one way of screen printing, and steel-printing.

5. The method as claimed in claim 2, wherein in the step of filling elastomer, the photo-resistors are directly used as elastomers by a step of remaining the photo-resistor on the pad as an elastomer.

6. The method as claimed in claim 2, wherein the elastomers are added by one of coating, plating, and dry filming.

7. The method of claim 2, wherein the elastomer is selected from one of silicone and compound material.
